(19) United States
(12) Patent Application Publication
(10) Pub. No.: US 2026/0044267 A1
(43) Pub. Date: Feb. 12, 2026

(54) SEMICONDUCTOR APPARATUS

(71) Applicant: SK hynix Inc., Icheon-si Gyeonggi-do (KR)

(72) Inventor: Chang Hyun KIM, Icheon-si Gyeonggi-do (KR)

(73) Assignee: SK hynix Inc., Icheon-si Gyeonggi-do (KR)

(21) Appl. No.: 19/007,856

(22) Filed: Jan. 2, 2025

(30) Foreign Application Priority Data
Aug. 6, 2024 (KR) 10-2024-0104771

(51) Int. Cl. G06F 3/06

(52) U.S. Cl. CPC G06F 3/0622; G06F 3/0637; G06F 3/0673

(57) ABSTRACT

A semiconductor apparatus comprises a memory region, generates an invalid access flag signal indicating an invalid access to the memory region based on a row address signal input with a read command, and blocks data output in response to the invalid access flag signal.

### CROSS-REFERENCES TO RELATED APPLICATION

The present application claims priority under 35 U.S.C. § 119(a) to Korean application number 10-2024-0104771 filed on Aug. 6, 2024, in the Korean Intellectual Property Office, which application is incorporated herein by reference in its entirety.

### BACKGROUND

### 1.Technical Field

Various embodiments generally relate to a semiconductor circuit, and, more particularly, to a semiconductor apparatus capable of controlling data output in response to an invalid access.

### 2. Related Art

A semiconductor apparatus, for example, a semiconductor memory device, outputs data in response to an access from a host, for example, a read command and a corresponding address signal.

The host may attempt an invalid access to the semiconductor apparatus for various reasons. An invalid access includes a situation in which an address signal provided by the host, particularly a row address signal, indicates that the region specified by the row address signal does not exist in a memory region of the semiconductor apparatus.

In response to the invalid access from the host, the semiconductor apparatus performs a column operation and outputs data of global I/O lines driven by a previous read operation or a write operation. At this time, the data output is not only meaningless, but also causes security problems of a memory system including the semiconductor circuit.

### SUMMARY

In an embodiment, a semiconductor apparatus may comprise a memory region, may be configured to generate an invalid access flag signal indicating an invalid access to the memory region based on a row address signal input with a read command, and may be configured to block data output in response to the invalid access flag signal.

In an embodiment, a semiconductor apparatus may include a memory region, a flag signal generation circuit, and a column decoder. The memory region may be coupled to a first data input/output line and may be configured to output data in response to a column selection signal. The flag signal generation circuit may be configured to generate an invalid access flag signal in response to a row address signal. The column decoder may be configured to be coupled between the first data input/output line and a second data input/output line, and may be configured to perform an operation that generates the column selection signal in response to at least one of a column address signal, a read command, and the invalid access flag signal and to perform an operation that transmits data from the first data input/output line to the second data input/output line.

In an embodiment, a semiconductor apparatus may include a memory region, a flag signal generation circuit, and a column decoder. The memory region may be coupled to a first data input/output line and may be configured to output data in response to a column selection signal. The flag signal generation circuit may be configured to generate an invalid access flag signal based on a row address signal and a memory capacity information signal, a value of the memory capacity information signal being set according to a memory capacity of the memory region. The column decoder may be configured to be coupled between the first data input/output line and a second data input/output line, and may be configured to perform an operation that generates the column selection signal in response to at least one of a column address signal, a read command, and the invalid access flag signal, and to perform an operation that transmits data from the first data input/output line to the second data input/output line.

### BRIEF DESCRIPTION OF THE DRAWINGS

FIG. 1 is a diagram illustrating a semiconductor apparatus according to an embodiment of the present disclosure.

FIG. 2 is a diagram illustrating a flag signal generation circuit of FIG. 1.

FIG. 3 is a diagram illustrating a column decoder according to an embodiment of a first data output control method.

FIG. 4 is a diagram illustrating a column decoder according to an embodiment of a first data output control method.

FIG. 5 is a diagram illustrating a first data output control method according to an embodiment of the present disclosure.

FIG. 6 is a diagram illustrating a column decoder according to an embodiment of a second data output control method.

FIG. 7 is a diagram illustrating a second data output control method according to an embodiment of the present disclosure.

FIG. 8 is a diagram illustrating a column decoder according to an embodiment of a third data output control method.

FIG. 9 is a diagram illustrating a third data output control method.

FIG. 10 is a diagram illustrating a semiconductor apparatus according to an embodiment of the present disclosure.

FIG. 11 is a diagram illustrating a flag signal generation circuit of FIG. 10.

### DETAILED DESCRIPTION

Various embodiments of the present disclosure can enhance the security of a system by blocking data output in response to an invalid access.

Hereinafter, embodiments of the present disclosure will be described in more detail with reference to the accompanying drawings.

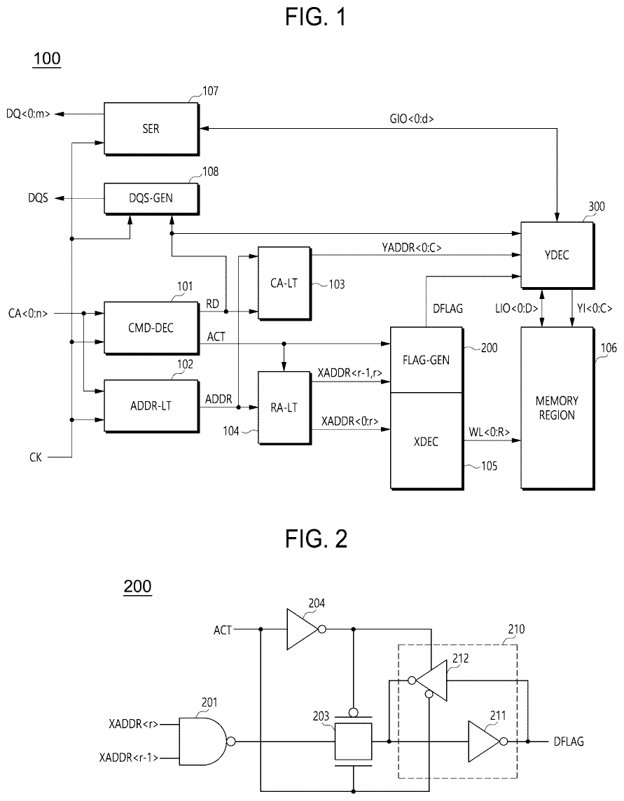

FIG. 1 is a diagram illustrating a semiconductor apparatus 100 according to an embodiment of the present disclosure.

Referring to FIG. 1, the semiconductor apparatus 100 may include a command decoder (CMD-DEC) 101, an address latch (ADDR-LT) 102, a column address latch (CA-LT) 103, a row address latch (RA-LT) 104, a row decoder (XDEC) 105, a memory region 106, a serialization circuit (SER) 107, a strobe signal generation circuit (DQS-GEN) 108, a flag signal generation circuit (FLAG-GEN) 200, and a column decoder (YDEC) 300.

The command decoder 101 may receive a command/address signal CA<0:n> and a clock signal CK and may output various commands, including a read command RD and an active command ACT. The command decoder 101 may decode command-related signals included in the command/address signal CA<0:n> and may output various commands including the read command RD and the active command ACT.

The address latch 102 may receive the command/address signal CA<0:n> and the clock signal CK and may output an address signal ADDR. The address latch 102 may latch address-related signals included in the command/address signal CA<0:n> and may output them as the address signal ADDR.

The column address latch 103 may latch and output a column address signal YADDR<0:C> from the address signal ADDR in response to the read command RD.

The row address latch 104 may latch and output a row address signal XADDR<0:r> from the address signal ADDR in response to the active command ACT.

The memory region 106 may be coupled to a plurality of first data input/output lines LIO<0:D> and may output data in response to a column selection signal YI<0:C>.

The memory region 106 may include a plurality of unit memory cells, and the plurality of unit memory cells may include at least one of a volatile memory and a non-volatile memory. The volatile memory may include SRAM (Static RAM), DRAM (Dynamic RAM), SDRAM (Synchronous DRAM), and the non-volatile memory may include ROM (Read Only Memory), PROM (Programmable ROM), EEPROM (Electrically Erase and Programmable ROM), EPROM (Electrically Programmable ROM), flash memory, PRAM (Phase change RAM), MRAM (Magnetic RAM), RRAM (Resistive RAM), and FRAM (Ferroelectric RAM).

The row decoder 105 may decode the row address signal XADDR<0:r> to activate one wordline corresponding to a decoded row address signal among a plurality of wordlines WL<0:R> in the memory region 106.

The serialization circuit 107 may serialize data transmitted through a plurality of second data input/output lines GIO<0:d> according to the clock signal CK and may output the data to data input/output pads DQ<0:m>.

The strobe signal generation circuit 108 may receive the read command RD and the clock signal CK and may output a strobe signal DQS. The strobe signal generation circuit 108 may generate and output the strobe signal DQS according to the clock signal CK when the read command RD is input.

The flag signal generation circuit 200 may receive a portion of the row address signal XADDR<0:r>, namely, the most significant bit XADDR<r> and the second most significant bit XADDR<r-1>, and the active command ACT and may output an invalid access flag signal DFLAG.

The flag signal generation circuit 200 may activate the invalid access flag signal DFLAG when both the most significant bit XADDR<r> and the second most significant bit XADDR<r-1> of the row address signal XADDR<0:r> are at a first logic level, for example, a high level. The memory region 106 may have a variety of memory capacities. For example, if the memory capacity of the memory region 106 is a multiple of 3, such as 12 GB, 24 GB, or the like, then when both the most significant bit XADDR<r> and the second most significant bit XADDR<r-1> of the row address signal XADDR<0:r> are at a high logic level, a location may be specified that does not exist in the memory region 106. Therefore, the semiconductor apparatus 100 according to an embodiment of the present disclosure may cause the flag signal generation circuit 200 to detect whether the most significant bit XADDR<r> and the second most significant bit XADDR<r-1> of the row address signal XADDR<0:r> are both at a high level and to generate the invalid access flag signal DFLAG to define whether an access is an invalid access to the semiconductor apparatus 100.

The column decoder 300 may receive the read command RD, the column address signal YADDR<0:C>, and the invalid access flag signal DFLAG as inputs and may output the column selection signal YI<0:C>. The column decoder 300 may be coupled between the plurality of first data input/output lines LIO<0:D> and the plurality of second data input/output lines GIO<0:d>. The column decoder 300 may perform an operation to generate the column selection signal YI<0:C> according to at least one of the read command RD, the column address signal YADDR<0:C>, and the invalid access flag signal DFLAG and may perform an operation to transmit data of the plurality of first data input/output lines LIO<0:D> to the plurality of second data input/output lines GIO<0:d>.

When the invalid access flag signal DFLAG is activated, the column decoder 300 may generate the column selection signal YI<0:C> according to the column address signal YADDR<0:C> and the read command RD and may fix the level of the plurality of second data input/output lines GIO<0:d> to a predetermined logic level regardless of the data of the plurality of first data input/output lines LIO<0:D>. The predetermined logic level may be a low level or a high level.

When the invalid access flag signal DFLAG is deactivated, the column decoder 300 may generate the column selection signal YI<0:C> based on the column address signal YADDR<0:C> and the read command RD. When the invalid access flag signal DFLAG is activated, the column decoder 300 may deactivate the column selection signal YI<0:C> regardless of the column address signal YADDR<0:C> and the read command RD and may fix the level of the plurality of second data input/output lines GIO<0:d> to a predetermined logic level regardless of the data of the plurality of first data input/output lines LIO<0:D>.

Hereinafter, a method of fixing the level of the plurality of second data input/output lines GIO<0:d> to a low logic level when the invalid access flag signal DFLAG is activated will be referred to as a first data output control method, a method of fixing the level of the plurality of second data input/output lines GIO<0:d> to a high logic level when the invalid access flag signal DFLAG is activated will be referred to as a second data output control method, and a method of deactivating the column selection signal YI<0:C> and fixing the level of the plurality of second data input/output lines GIO<0:d> to a low logic level or a high logic level when the invalid access flag signal DFLAG is activated will be referred to as a third data output control method.

FIG. 2 is a diagram illustrating the flag signal generation circuit 200 of FIG. 1.

Referring to FIG. 2, the flag signal generation circuit 200 may include first to third logic gates 201, 203, and 204 and a latch circuit 210.

The first logic gate 201 may output a result from performing a NAND operation on the most significant bit XADDR<r> and the second most significant bit XADDR<r-1> of the row address signal XADDR<0:r>. The second logic gate 203 may receive an active command ACT that is input to a non-inverting control terminal and an inverted active command ACT that is input to an inverting control terminal. The second logic gate 203 may pass an output of the first logic gate 201 when the active command ACT is activated to a high level. The third logic gate 204 may invert and output the active command ACT and to the inverting control terminal of the second logic gate 203. The latch circuit 210 may latch an output of the second logic gate 203 for a duration of time corresponding to the active command ACT being at a low level and may output a latched signal as the invalid access flag signal DFLAG. The latch circuit may 210 may include an inverter 211 and a tri-state inverter 212. The inverter 211 may invert and output the output of the second logic gate 203 as the invalid access flag signal DFLAG. The tri-state inverter 212 may receive the active command ACT through its non-inverting control terminal and inverting control terminal. The active command ACT received through the non-inverting control terminal may be inverted through the third logic gate 204. The active command ACT received through the inverting control terminal may be received from an output of the inverter 211 and may be fed back to an input of the inverter 211.

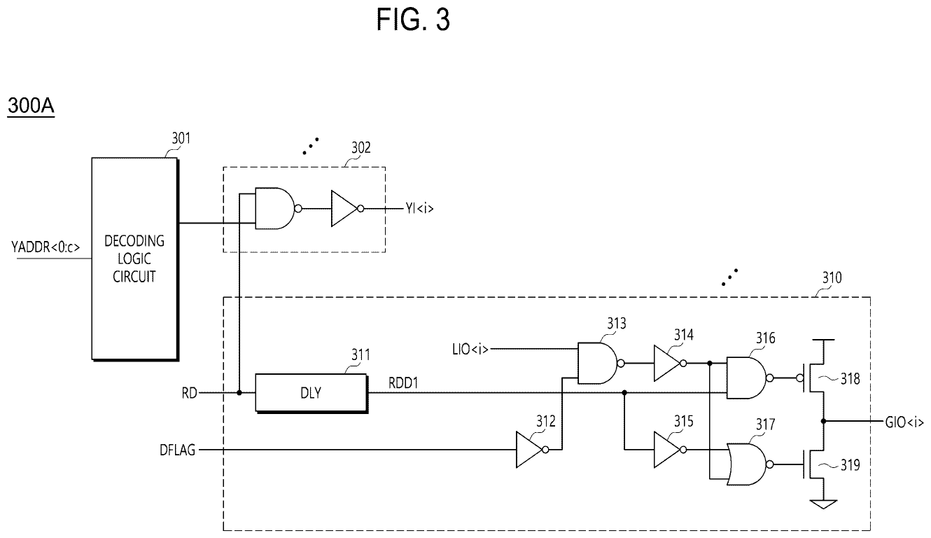

FIG. 3 is a diagram illustrating a column decoder 300A according to an embodiment of the first data output control method.

Referring to FIG. 3, the column decoder 300A may include a decoding logic circuit 301, a column selection signal generation circuit 302, and a data input/output line driving circuit 310.

The decoding logic circuit 301 may decode a column address signal YADDR<0:C> and may output its result.

The column selection signal generation circuit 302 may output a result from performing an AND operation on one of the output signals of the decoding logic circuit 301 and the read command RD as one signal YI<i> of the plurality of column selection signals YI<0:C>.

The column selection signal generation circuit 302 may be provided with a number corresponding to the number of output signals of the decoding logic circuit 301.

In response to a deactivation of the invalid access flag signal DFLAG, the data input/output line driving circuit 310 may drive the plurality of second data input/output lines GIO<0:d> to match the data of the plurality of first data input/output lines LIO<0:D>. In response to activation of the invalid access flag signal DFLAG, the data input/output line driving circuit 310 may fix the level of the plurality of second data input/output lines GIO<0:d> to a low level regardless of the data of the plurality of first data input/output lines LIO<0:D>.

The data input/output line driving circuit 310 may include a delay circuit DLY 311, a plurality of logic gates 312, 313, 314, 315, 316, and 317, and drivers 318 and 319. The delay circuit 311 may delay the read command RD by a set time and may output a first delay signal RDD1. The first logic gate 312 may invert the invalid access flag signal DFLAG. The second logic gate 313 and the third logic gate 314 may output a result from performing an AND operation on one signal LIO<i> of the plurality of first data input/output lines LIO<0:D> at a specific logic level and an output of the first logic gate 312. The fourth logic gate 315 may invert the first delay signal RDD1. The fifth logic gate 316 may output a result from performing a NAND operation on an output of the third logic gate 314 and the first delay signal RDD1. The sixth logic gate 317 may output a result from performing NOR operation on an output of the third logic gate 314 and an output of the fourth logic gate 315. The drivers 318 and 319 may drive one signal GIO<i> of the plurality of second data input/output lines GIO<0:d> with a power voltage level based on an output of the fifth logic gate 316 or may drive one signal GIO<i> of the plurality of second data input/output lines GIO<0:d> with a ground voltage level based on an output of the sixth logic gate 317. The data input/output line driving circuit 310 may be provided with a number corresponding to the number of the plurality of first data input/output lines LIO<0:D>.

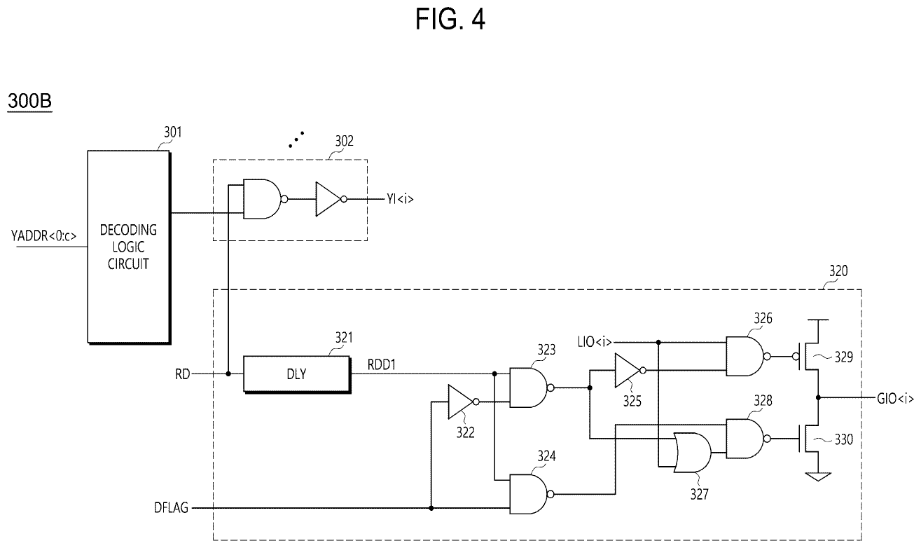

FIG. 4 is a diagram illustrating a column decoder 300B according to an embodiment of the first data output control method.

Referring to FIG. 4, the column decoder 300B may include a decoding logic circuit 301, a column selection signal generation circuit 302, and a data input/output line driving circuit 320.

The decoding logic circuit 301 may decode a column address signal YADDR<0:C> and may output its result.

The column selection signal generation circuit 302 may output a result from performing an AND operation on one of output signals of the decoding logic circuit 301 and the read command RD as one signal YI<i> of the plurality of column selection signals YI<0:C>. The column selection signal generation circuit 302 may be provided with a number corresponding to the number of output signals of the decoding logic circuit 301.

In response to a deactivation of the invalid access flag signal DFLAG, the data input/output line driving circuit 320 may drive the plurality of second data input/output lines GIO<0:d > to match the data of the plurality of first data input/output lines LIO<0:D>. In response to activation of the invalid access flag signal DFLAG, the data input/output line driving circuit 320 may fix the level of the plurality of second data input/output lines GIO<0:d> to a low level regardless of data of the plurality of first data input/output lines LIO<0:D>.

The data input/output line driving circuit 320 may include a delay circuit DLY 321, a plurality of logic gates 322, 323, 324, 325, 326, 327, and 328, and drivers 329 and 330. The delay circuit 321 may delay the read command RD by a set time and may output a first delay signal RDD1. The first logic gate 322 may invert the invalid access flag signal DFLAG. The second logic gate 323 may output a result from performing a NAND operation on the first delay signal RDD1 and an output of the first logic gate 322. The third logic gate 324 may output a result from performing a NAND operation on the first delay signal RDD1 and the invalid access flag signal DFLAG. The fourth logic gate 325 may invert an output of the second logic gate 323. The fifth logic gate 326 may output a result from performing a NAND operation on one signal LIO<i> of the plurality of first data input/output lines

LIO<0:D> at a specific logic level and an output of the fourth logic gate 325. The sixth logic gate 327 may output a result from performing an OR operation on the output of the second logic gate 323 and the logic level of one signal LIO<i> of the plurality of first data input/output lines LIO<0:D>. The seventh logic gate 328 may output a result from performing a NAND operation on an output of the third logic gate 324 and an output of the sixth logic gate 327. The drivers 329 and 330 may drive one signal GIO<i> of the plurality of second data input/output lines GIO<0:d> with a power voltage level based on an output of the fifth logic gate 326 or may drive one signal GIO<i> of the plurality of second data input/output lines GIO<0:d> with a ground voltage level based on an output of the seventh logic gate 328. The data input/output line driving circuit 320 may be provided with a number corresponding to the number of the plurality of first data input/output lines LIO<0:D>.

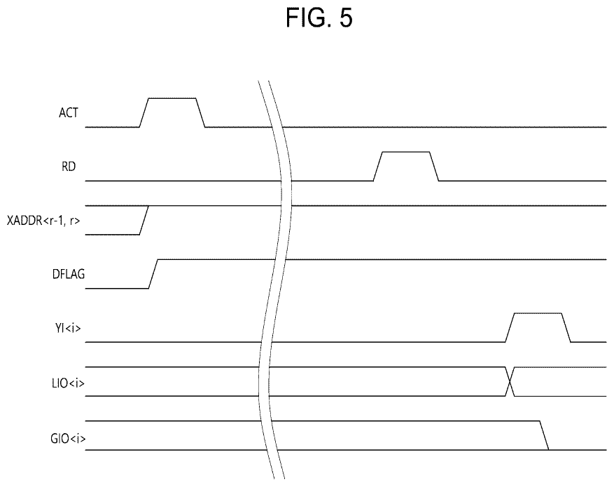

FIG. 5 is a diagram illustrating the first data output control method.

Referring to FIG. 5, the semiconductor apparatus 100 with the column decoder 300A, according to FIG. 3, or the column decoder 300B, according to FIG. 4, may activate the invalid access flag signal DFLAG to a high level when the most significant bit XADDR<r> and the second most significant bit XADDR<r-1> of the row address signal XADDR<0:r> are both at a high level.

When the read command RD is input and the column selection signal YI<i> is generated after a predetermined delay, data may be output from the memory region 106 through the first data input/output line LIO<i>. The word “predetermined” as used herein with respect to a parameter, such as a predetermined timing, time, or voltage level, means that a value for the parameter is determined prior to the parameter being used in a process or algorithm. For some embodiments, the value for the parameter is determined before the process or algorithm begins. In other embodiments, the value for the parameter is determined during the process or algorithm but before the parameter is used in the process or algorithm.

The data output by the read command RD may be blocked because the invalid access flag signal DFLAG is activated with a logic high level. The data output can be blocked because a level of the second data input/output line GIO<i> is fixed to a low level to match the first data output control method, regardless of a level of the first data input/output line LIO<i>, according to a high-level invalid access flag signal DFLAG. By detecting an invalid access to the semiconductor apparatus 100 and blocking the data output, it is possible to block meaningless data output and to prevent security problems from occurring in advance.

When the invalid access flag signal DFLAG is at a low level, data output from the memory region 106 may be delivered to the second data input/output line GIO<i> through the first data input/output line LIO<i> according to the plurality of column selection signals YI<0:C>.

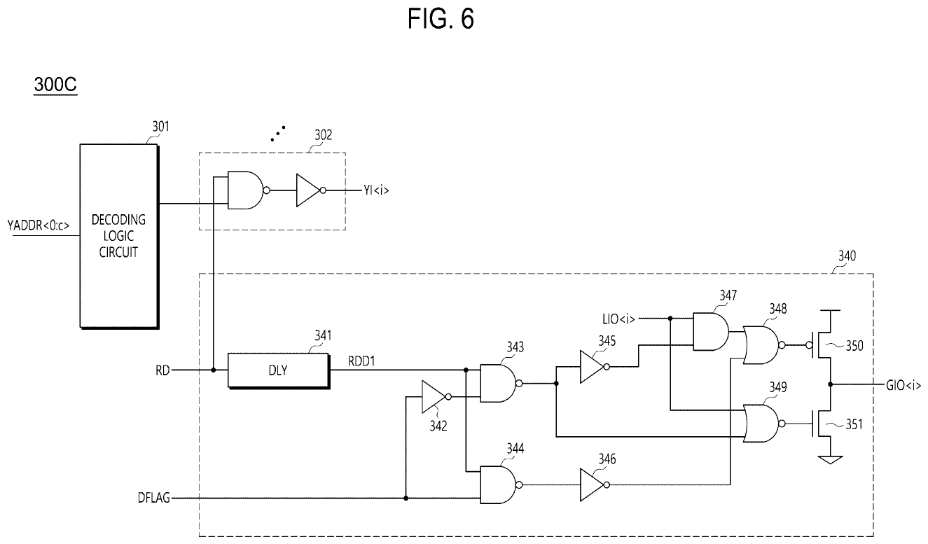

FIG. 6 is a diagram illustrating a column decoder 300C according to an embodiment of the second data output control method.

Referring to FIG. 6, the column decoder 300C may include a decoding logic circuit 301, a column selection signal generation circuit 302, and a data input/output line driving circuit 340.

The decoding logic circuit 301 may decode a column address signal YADDR<0:C> and may output its result.

The column selection signal generation circuit 302 may output a result from performing an AND operation on one of output signals of the decoding logic circuit 301 and the read command RD as one signal YI<i> of the plurality of column selection signals YI<0:C>. The column selection signal generation circuit 302 may be provided with a number corresponding to the number of output signals of the decoding logic circuit 301.

In response to deactivation of the invalid access flag signal DFLAG, the data input/output line driving circuit 340 may drive the plurality of second data input/output lines GIO<0:d > to match the data of the plurality of first data input/output lines LIO<0:D>. In response to activation of the invalid access flag signal DFLAG,, the data input/output line driving circuit 340 may fix the level of the plurality of second data input/output lines GIO<0:d> to a high level regardless of data of the plurality of first data input/output lines LIO<0:D>.

The data input/output line driving circuit 340 may include a delay circuit DLY 341, a plurality of logic gates 342, 343, 344, 345, 346, 347, 348, and 349, and drivers 350 and 351. The delay circuit 341 may delay the read command RD by a set time and may output a first delay signal RDD1. The first logic gate 342 may invert the invalid access flag signal DFLAG. The second logic gate 343 may output a result from performing a NAND operation on the first delay signal RDD1 and an output of the first logic gate 342. The third logic gate 344 may output a result from performing a NAND operation on the first delay signal RDD1 and the invalid access flag signal DFLAG. The fourth logic gate 345 may invert an output of the second logic gate 343. The fifth logic gate 346 may invert an output of the third logic gate 344. The sixth logic gate 347 may output a result from performing an AND operation on one signal LIO<i> of the plurality of first data input/output lines LIO<0:D> at a specific logic level and an output of the fourth logic gate 345. The seventh logic gate 348 may output a result from performing a NOR operation on an output of the sixth logic gate 347 and an output of the fifth logic gate 346. An eighth logic gate 349 may output a result from performing a NOR operation on a logic level LIO<i> of one signal LIO<0:D> of the plurality of first data input/output lines LIO<0:D> and the output of the second logic gate 343. The drivers 350 and 351 may drive one signal GIO<i> of the plurality of second data input/output lines GIO<0:d> with a power voltage level based on an output of the seventh logic gate 348 or may drive one signal GIO<i> of the plurality of second data input/output lines GIO<0:d> with a ground voltage level based on an output of the eighth logic gate 349. The data input/output line driving circuit 340 may be provided with a number corresponding to the number of the plurality of first data input/output lines LIO<0:D>.

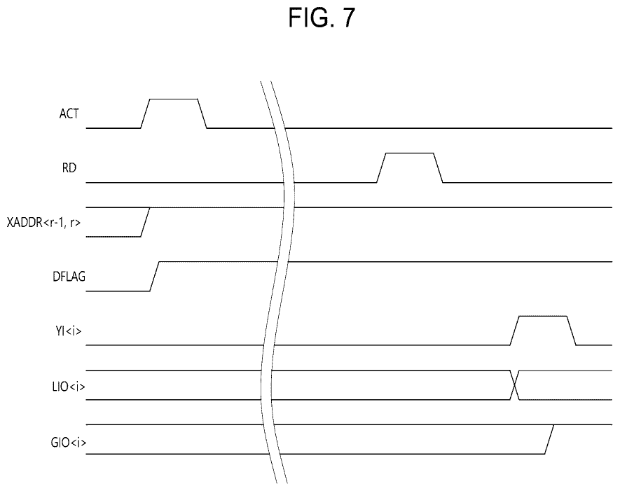

FIG. 7 is a diagram illustrating a second data output control method.

Referring to FIG. 7, the semiconductor apparatus 100 with the column decoder 300C, according to FIG. 6, may activate the invalid access flag signal DFLAG to a high level when the most significant bit XADDR<r> and the second most significant bit XADDR<r-1> of the row address signal XADDR<0:r> are both at a high level.

When the read command RD is input and the column selection signal YI<i> is generated after a predetermined delay, data may be output from the memory region 106 through the first data input/output line LIO<i>.

The data output by the read command RD may be blocked because the invalid access flag signal DFLAG is activated with a logic high level. The data output can be blocked because the level of the second data input/output line GIO<i> is fixed to a high level to match the second data output control method regardless of a level of the first data input/output line LIO<i> according to a high-level invalid access flag signal DFLAG. By detecting an invalid access to the semiconductor apparatus 100 and blocking the data output, it is possible to block meaningless data output and to prevent security problems from occurring in advance.

When the invalid access flag signal DFLAG is at a low level, data output from the memory region 106 may be delivered to the second data input/output line GIO<i> through the first data input/output line LIO<i> according to the plurality of column selection signals YI<0:C>.

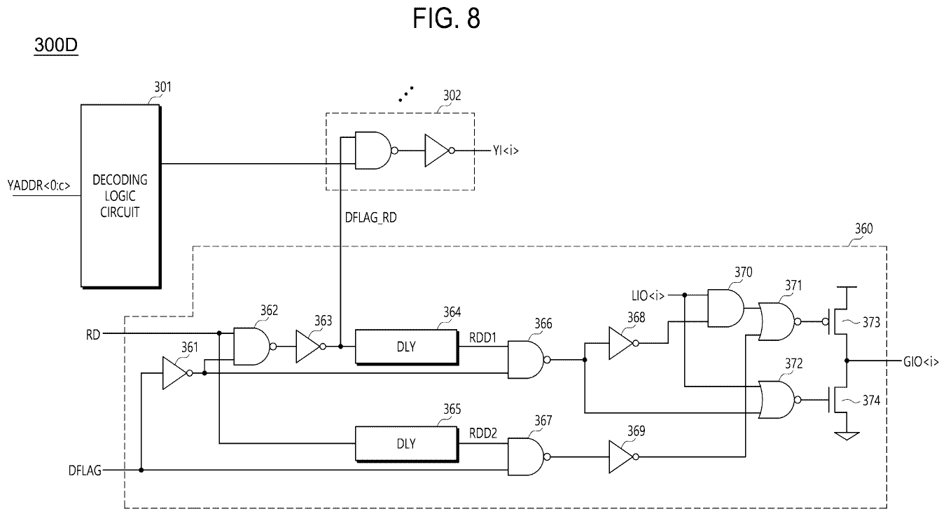

FIG. 8 is a diagram illustrating a column decoder 300D according to an embodiment of the third data output control method.

Referring to FIG. 8, the column decoder 300D may include a decoding logic circuit 301, a column selection signal generation circuit 302, and a data input/output line driving circuit 360.

The decoding logic circuit 301 may decode a column address signal YADDR<0:C> and may output its result.

The column selection signal generation circuit 302 may output a result from performing an AND operation on one of output signals of the decoding logic circuit 301 and an integrated signal DFLAG-RD as one signal YI<i> of the plurality of column selection signals YI<0:C>. The column selection signal generation circuit 302 may be provided with a number corresponding to the number of output signals of the decoding logic circuit 301.

In response to deactivation of the invalid access flag signal DFLAG, the data input/output line driving circuit 360 may drive the plurality of second data input/output lines GIO<0:d> to match the data of the plurality of first data input/output lines LIO<0:D>. In response to activation of the invalid access flag signal DFLAG, the data input/output line driving circuit 360 may fix the level of the plurality of second data input/output lines GIO<0:d> to a high level regardless of data of the plurality of first data input/output lines LIO<0:D>, and block generating the column selection signal YI<0:C>.

The data input/output line driving circuit 360 may include a plurality of logic gates 361, 362, 363, 366, 367, 368, 369, 370, 371, and 372, a first delay circuit 364, a second delay circuit 365, and drivers 373 and 374. The first logic gate 361 may invert the invalid access flag signal DFLAG. The second logic gate 362 and the third logic gate 363 may output a result from performing an AND operation on the read command RD and an output of the first logic gate 361 as the integrated signal DFLAG-RD. The first delay circuit 364 may delay the integrated signal DFLAG-RD by a set time and may output a first delay signal RDD1. The second delay circuit 365 may delay the read command RD by a set time and may output a second delay signal RDD2. The fourth logic gate 366 may output a result from performing a NAND operation on the first delay signal RDD1 and an output of the first logic gate 361. The fifth logic gate 367 may output a result from performing a NAND operation on the second delay signal RDD2 and the invalid access flag signal DFLAG. The sixth logic gate 368 may invert an output of the fourth logic gate 366. The seventh logic gate 369 may invert an output of the fifth logic gate 367. An eighth logic gate 370 may output a result from performing an AND operation on one signal LIO<i> of the plurality of first data input/output lines LIO<0:D> at a specific logic level and an output of the sixth logic gate 368. The ninth logic gate 371 may output a result from performing a NOR operation on an output of the eighth logic gate 370 and an output of the seventh logic gate 369. The tenth logic gate 372 may output a result from performing a NOR operation on a logic level LIO<i> of one signal LIO<0:D> of the plurality of first data input/output lines LIO<0:D> and the output of the fourth logic gate 366. The drivers 373 and 374 may drive one signal GIO<i> of the plurality of second data input/output lines GIO<0:d>with a power voltage level based on an output of the ninth logic gate 371 or may drive one signal GIO<i> of the plurality of second data input/output lines GIO<0:d> with a ground voltage level based on an output of the tenth logic gate 372. The data input/output line driving circuit 360 may be provided with a number corresponding to the number of the plurality of first data input/output lines LIO<0:D>.

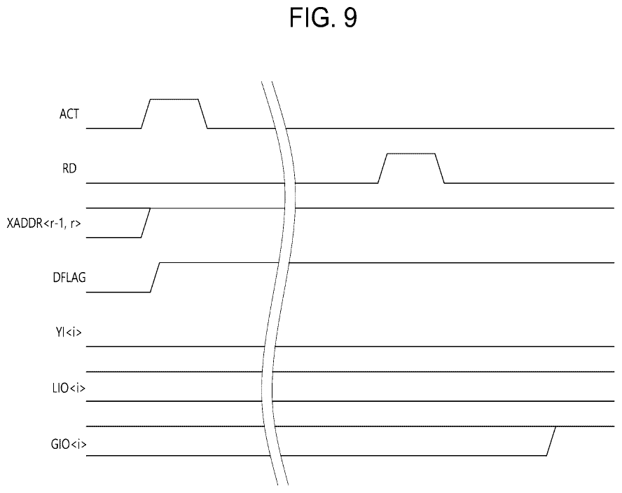

FIG. 9 is a diagram illustrating the third data output control method.

Referring to FIG. 9, the semiconductor apparatus 100 with the column decoder 300D, according to FIG. 8, may activate the invalid access flag signal DFLAG to a high level when the most significant bit XADDR<r> and the second most significant bit XADDR<r-1> of the row address signal XADDR<0:r> are both at a high level.

Because the invalid access flag signal DFLAG is at a high level, the integrated signal DFLAG-RD may be generated with a logic low level regardless of the read command RD. Because the integrated signal DFLAG-RD is at a low level, the generation of the plurality of column selection signals YI<0:C> is blocked.

Because the generation of the plurality of column selection signals YI<0:C> is blocked, data output from the memory region 106 through the first data input/output line LIO<i> may be blocked.

According to a high-level invalid access flag signal DFLAG, the level of the second data input/output line GIO<i> may be fixed to a high level regardless of a level of the first data input/output line LIO<i>, so that data output can be blocked. By detecting an invalid access to the semiconductor apparatus 100 and fixing the level of the second data input/output line GIO<i> to a high level, as well as blocking the data output of the memory region 106 itself, meaningless data output can be blocked, security problems can be prevented in advance, and unnecessary current consumption can be prevented.

When the invalid access flag signal DFLAG is at a low level, data output from the memory region 106 may be transmitted to the second data input/output line GIO<i> through the first data input/output line LIO<i> according to the plurality of column selection signals YI<0:C>.

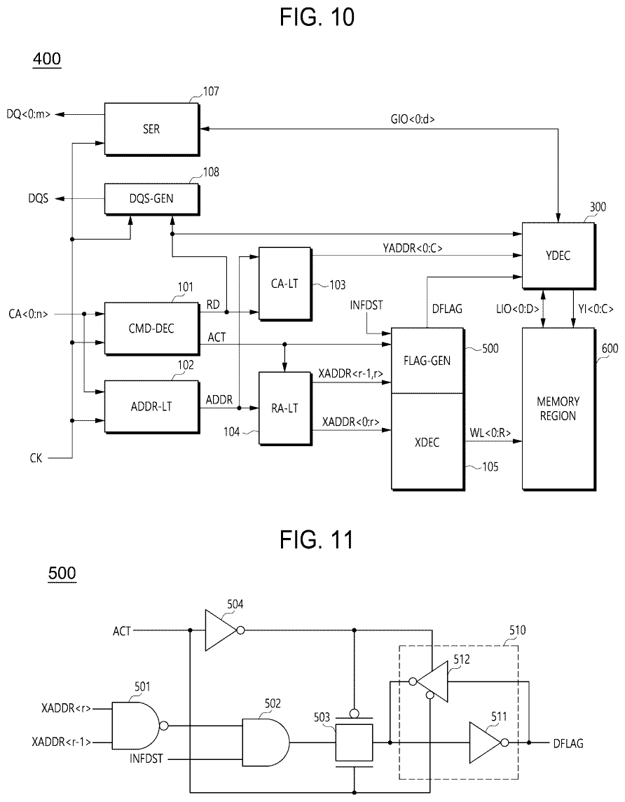

FIG. 10 is a diagram illustrating a semiconductor apparatus 400 according to an embodiment of the present disclosure.

The semiconductor apparatus 400 may activate the invalid access flag signal DFLAG when the most significant bit XADDR<r> and the second most significant bit XADDR<r-1> of the row address signal XADDR<0:r> are both at a first logic level (e.g., high level) and the memory region 106 has a memory capacity equal to a multiple of three.

When the semiconductor apparatus 400 activates the invalid access flag signal DFLAG, the semiconductor apparatus 400 may block data output through the plurality of second data input/output lines GIO<0:d> by fixing the plurality of second data input/output lines GIO<0:d> to a low level to match the first data output control method.

The semiconductor apparatus 400 may block data output through the plurality of second data input/output lines GIO<0:d> by fixing the plurality of second data input/output lines GIO<0:d> to a high level to match the second data output control method.

The semiconductor apparatus 400 may block data output through the plurality of second data input/output lines GIO<0:d> by fixing the plurality of second data input/output lines GIO<0:d> to a predetermined logic level to match the third data output control method, while also blocking data output through the plurality of first data input/output lines LIO<0:D> in the memory region 106.

Referring to FIG. 10, the semiconductor apparatus 400 may include a command decoder (CMD-DEC) 101, an address latch (ADDR-LT) 102, a column address latch (CA-LT) 103, a row address latch (RA-LT) 104, a row decoder (XDEC) 105, a memory region 600, a serialization circuit (SER) 107, a strobe signal generation circuit (DQS-GEN) 108, a flag signal generation circuit (FLAG-GEN) 500, and a column decoder (YDEC) 300.

The command decoder 101, the address latch 102, the column address latch 103, the row address latch 104, the row decoder 105, the serialization circuit 107, and the strobe signal generation circuit 108 may be configured as shown in FIG. 1.

The flag signal generation circuit 500 may receive a portion of the row address signal XADDR<0:r>, namely the most significant bit XADDR<r> and the second most significant bit XADDR<r-1>, the active command ACT, and a memory capacity information signal INFDST as inputs and may output the invalid access flag signal DFLAG. The memory capacity information signal INFDST may be a first logic level (e.g., a high level) when the memory capacity of the memory region 600 is a multiple of three and may be a second logic level (e.g., a low level) when the memory capacity of the memory region 600 is a multiple of two. The semiconductor apparatus 400 may include various characteristic information, including memory capacity. The memory capacity information signal INFDST may be generated using information regarding the memory capacity among embedded information.

The flag signal generation circuit 500 may activate the invalid access flag signal DFLAG when the most significant bit XADDR<r> and the second most significant bit XADDR<r-1> of the row address signal XADDR<0:r> are both at a high level and the memory capacity information signal INFDST is at a high level.

The memory region 600 may be coupled to the plurality of first data input/output lines LIO<0:D> and may output data in response to the column selection signal YI<0:C>. The memory region 600 may be designed to have a memory capacity that is a multiple of two, such as 4 GB, 8 GB, 16 GB, 32 GB, or the like, or a multiple of three, such as 12 GB, 24 GB, or the like.

If the memory capacity of the memory region 106 is a multiple of three, then when both the most significant bit XADDR<r> and the second most significant bit XADDR<r-1> of the row address signal XADDR<0:r> are at a high logic level, they will specify a location that does not exist in the memory region 106. Therefore, the semiconductor apparatus 400 according to an embodiment of the present disclosure may cause the flag signal generation circuit 500 to detect whether the most significant bit XADDR<r> and the second most significant bit XADDR<r-1> of the row address signal XADDR<0:r> and the memory capacity information signal INFDST are both at a high level and to generate the invalid access flag signal DFLAG to define whether an access is an invalid access to the semiconductor apparatus 400.

The column decoder 300 may be configured the same as in FIG. 3, FIG. 4, FIG. 6, or FIG. 8.

FIG. 11 is a diagram illustrating the flag signal generation circuit 500 of FIG. 10.

Referring to FIG. 11, the flag signal generation circuit 500 may include first to fourth logic gates 501, 502, 503, and 504 and a latch circuit 510.

The first logic gate 501 may output a result from performing a NAND operation on the most significant bit XADDR<r> and the second most significant bit XADDR<r-1> of the row address signal XADDR<0:r>. The second logic gate 502 may output a result from performing an AND operation on an output of the first logic gate 501 and the memory capacity information signal INFDST. The third logic gate 503 may receive the active command ACT that is input to a non-inverting control terminal and an inverted active command ACT that is input to an inverting control terminal. The third logic gate 503 may pass an output of the second logic gate 502 when the active command ACT is activated to a high level. The fourth logic gate 504 may invert and output the active command ACT to the inverting control terminal of the third logic gate 503. The latch circuit 510 may latch an output of the third logic gate 503 for a duration of time corresponding to the active command ACT being at a low level and may output a latched signal as the invalid access flag signal DFLAG. The latch circuit 510 may include an inverter 511 and a tri-state inverter 512. The inverter 511 may invert and output the output of the third logic gate 503 as the invalid access flag signal DFLAG. The tri-state inverter 512 may receive the active command ACT through its non-inverting control terminal and inverting control terminal. The active command received through the non-inverting control terminal may be inverted through the fourth logic gate 504. The active command ACT received through the inverting control terminal may be received from an output of the inverter 511 and may be fed back to an input of the inverter 511. In the semiconductor apparatus 400 described with

reference to FIGS. 10 and 11, the memory capacity information signal INFDST may be set to a low level when the memory capacity of the memory region 600 is a multiple of two.

Because the memory capacity information signal INFDST is at a low level, the invalid access flag signal DFLAG may be deactivated to a low level even if both the most significant bit XADDR<r> and the second most significant bit XADDR<r-1> of the row address signal XADDR<0:r> are input with a high level.

Because the invalid access flag signal DFLAG is at a low level, data output from the memory region 106 according to the plurality of column selection signals YI<0:C> can be transmitted to the second data input/output line GIO<i> through the first data input/output line LIO<i>.

When the memory capacity of the memory region 600 is a multiple of two, the semiconductor apparatus 400 may perform a normal data output operation according to a corresponding row address signal XADDR<0:r> when a read command is input.

On the other hand, the semiconductor apparatus 400 may have the memory capacity information signal INFDST set to a high level when the memory capacity of the memory region 600 is a multiple of 3.

Because the memory capacity information signal INFDST is at a high level, when both the most significant bit XADDR<r> and the second most significant bit XADDR<r-1> of the row address signal XADDR<0:r> are input with a high level, the invalid access flag signal DFLAG may be activated to a high level.

In accordance with the first data output control method, the second data output control method, and the third data output control method, because the invalid access flag signal DFLAG is at a high level, data output through the plurality of second data input/output lines GIO<0:d> can be blocked, or data output through the plurality of second data input/output lines GIO<0:d> and data output through the plurality of first data input/output lines LIO<0:D> can be blocked.

A person skilled in the art to which the present disclosure pertains can understand that the present disclosure may be carried out in other specific forms without changing its technical spirit or essential features. Therefore, it should be understood that the embodiments described above are illustrative in all aspects, not limitative. The scope of the present disclosure is defined by the claims to be described below rather than the detailed description, and it should be construed that the meaning and scope of the claims and all changes or modified forms derived from the equivalent concept thereof are included in the scope of the present disclosure.

What is claimed is:

1. A semiconductor apparatus comprising a memory region, configured to generate an invalid access flag signal indicating an invalid access to the memory region based on a row address signal input with a read command and configured to block data output in response to the invalid access flag signal.

2. The semiconductor apparatus of claim 1, wherein the semiconductor apparatus is configured to activate the invalid access flag signal when some bits of the row address signal have a first logic level.

3. The semiconductor apparatus of claim 1, wherein the semiconductor apparatus is configured to fix a level of data input/output lines to a predetermined logic level regardless of data output from the memory region when the invalid access flag signal is activated.

4. The semiconductor apparatus of claim 1, wherein the semiconductor apparatus is configured to block data from being output from the memory region when the invalid access flag signal is activated.

5. The semiconductor apparatus of claim 1, wherein the semiconductor apparatus is configured to activate the invalid access flag signal when both the most significant bit and the second most significant bit of the row address signal are at a first logic level and the memory region has a memory capacity equal to a multiple of three.

6. A semiconductor apparatus, comprising:
a memory region coupled to a first data input/output line and configured to output data in response to a column selection signal;
a flag signal generation circuit configured to generate an invalid access flag signal in response to a row address signal; and
a column decoder configured to be coupled between the first data input/output line and a second data input/output line and configured to:
perform an operation that generates the column selection signal in response to at least one of a column address signal, a read command, and the invalid access flag signal, and
perform an operation that transmits data from the first data input/output line to the second data input/output line.

7. The semiconductor apparatus of claim 6, wherein the flag signal generation circuit is configured to generate the invalid access flag signal based on an active command and the most significant bit and the second most significant bit of the row address signal.

8. The semiconductor apparatus of claim 7, wherein the flag signal generation circuit comprises:
a first logic gate that receives the most significant bit and the second most significant bit of the row address signal;
a second logic gate that passes an output of the first logic gate in response to the active command; and
a latch circuit that latches an output of the second logic gate in response to the active command to output the output of the second logic gate as the invalid access flag signal.

9. The semiconductor apparatus of claim 6, wherein, when the invalid access flag signal is activated, the column decoder is configured to generate the column selection signal in response to the column address signal and the read command and configured to fix a level of the second data input/output line to a predetermined logic level regardless of data of the first data input/output line.

10. The semiconductor apparatus of claim 9, wherein the column decoder comprises:
a decoding logic circuit configured to decode the column address signal;
a column selection signal generation circuit configured to output a signal combining an output of the decoding logic circuit and the read command as the column selection signal; and
a data input/output line driving circuit configured to drive the second data input/output line to match data of the first data input/output line in response to a deactivation of the invalid access flag signal and configured to fix a level of the second data input/output line to the predetermined logic level regardless of data of the first data input/output line in response to an activation of the invalid access flag signal.

11. The semiconductor apparatus of claim 6, wherein the column decoder is configured to:
generate the column selection signal in response to the column address signal and the read command when the invalid access flag signal is deactivated; and
deactivate the column selection signal regardless of the column address signal and the read command and fix a level of the second data input/output line to a predetermined logic level regardless of data of the first data input/output line when the invalid access flag signal is activated.

12. The semiconductor apparatus of claim 11, wherein the column decoder comprises:
a decoding logic circuit configured to decode the column address signal;
a column selection signal generation circuit configured to output a signal combining an output of the decoding logic circuit, the read command, and the invalid access flag signal as the column selection signal; and
a data input/output line driving circuit configured to drive the second data input/output line to match data of the first data input/output line in response to a deactivation of the invalid access flag signal and configured to fix a level of the second data input/output line to the predetermined logic level regardless of data of the first data input/output line in response to an activation of the invalid access flag signal.

13. A semiconductor apparatus, comprising:
a memory region coupled to a first data input/output line and configured to output data in response to a column selection signal;
a flag signal generation circuit configured to generate an invalid access flag signal based on a row address signal and a memory capacity information signal, a value of the memory capacity information signal being set according to a memory capacity of the memory region; and
a column decoder configured to be coupled between the first data input/output line and a second data input/output line and configured to:
perform an operation that generates the column selection signal in response to at least one of a column address signal, a read command, and the invalid access flag signal, and
perform an operation that transmits data from the first data input/output line to the second data input/output line.

14. The semiconductor apparatus of claim 13, wherein the flag signal generation circuit is configured to generate the invalid access flag signal based on an active command, the memory capacity information signal, and the most significant bit and the second most significant bit of the row address signal.

15. The semiconductor apparatus of claim 13, wherein the flag signal generation circuit is configured to deactivate the invalid access flag signal regardless of the row address signal when the memory capacity information signal has a value corresponding to the memory capacity of the memory region being a multiple of two and configured to activate the invalid access flag signal according to a logic level of the most significant bit and the second most significant bit of the row address signal when the memory capacity information signal has a value corresponding to the memory capacity of the memory region being a multiple of three.

16. The semiconductor apparatus of claim 13, wherein, when the invalid access flag signal is activated, the column decoder is configured to generate the column selection signal in response to the column address signal and the read command and configured to fix a level of the second data input/output line to a predetermined logic level regardless of data of the first data input/output line.

17. The semiconductor apparatus of claim 16, wherein the column decoder comprises:
a decoding logic circuit configured to decode the column address signal;
a column selection signal generation circuit configured to output a signal combining an output of the decoding logic circuit and the read command as the column selection signal; and
a data input/output line driving circuit configured to drive the second data input/output line to match data of the first data input/output line in response to a deactivation of the invalid access flag signal, and configured to fix a level of the second data input/output line to the predetermined logic level regardless of data of the first data input/output line in response to an activation of the invalid access flag signal.

18. The semiconductor apparatus of claim 13 wherein the column decoder is configured to:
generate the column selection signal in response to the column address signal and the read command when the invalid access flag signal is deactivated; and
deactivate the column selection signal regardless of the column address signal and the read command and fix a level of the second data input/output line to a predetermined logic level regardless of data of the first data input/output line when the invalid access flag signal is activated.

19. The semiconductor apparatus of claim 18, wherein the column decoder comprises:
a decoding logic circuit configured to decode the column address signal;
a column selection signal generation circuit configured to output a signal combining an output of the decoding logic circuit, the read command, and the invalid access flag signal as the column selection signal; and
a data input/output line driving circuit configured to drive the second data input/output line to match data of the first data input/output line in response to a deactivation of the invalid access flag signal, and configured to fix a level of the second data input/output line to the predetermined logic level regardless of data of the first data input/output line in response to an activation of the invalid access flag signal.
